(19) United States
(12) Patent Application Publication
(10) Pub. No.: US 2024/0044834 A1
(43) Pub. Date: Feb. 8, 2024

(54) OXYGEN CONTENT DETECTING SYSTEM AND CONTROL METHOD THEREOF

(71) Applicant: Illinois Tool Works Inc., Glenview, IL (US)

(72) Inventor: Yuexin Chen, Glenview, IL (US)

(21) Appl. No.: 18/268,862

(22) PCT Filed: Feb. 11, 2022
(86) PCT No.: PCT/US2022/016147

§ 371 Date: Jun. 21, 2023

(30) Foreign Application Priority Data
Mar. 1, 2021 (CN) 202110226394.2

(51) Int. Cl. G01N 27/409; B23K 3/08; G01N 27/419

(52) U.S. Cl. CPC G01N 27/409; B23K 3/08; G01N 27/419; H05K 3/34

(57) ABSTRACT

An oxygen content detection system, comprising: a zirconia analyser, an air source, a mass flow valve and a first throttle valve. The zirconia analyser comprises: a signal processing apparatus, a housing and a probe. The housing is connected to the signal processing apparatus, and has a detection port configured to enable a gas from inside the hearth to enter a cavity of the housing via the detection port; the probe is disposed in the cavity of the housing, has one end connected to the signal processing apparatus, and is GC configured to detect an oxygen concentration in the gas that enters the cavity of the housing, and the signal processing apparatus receives and processes a detection result of the probe in order to generate an oxygen concentration signal; the housing is further provided with a communication hole in fluid communication with the cavity of the housing, and the air source is configured to be connected to the communication hole via a connection pathway, in order to input air to the cavity of the housing. The mass flow valve is disposed in the connection pathway, and configured to adjust the amount of air according to the oxygen concentration signal. The first throttle valve is disposed in the connection pathway, in order to adjust the flow speed of air in the connection pathway.

### TECHNICAL FIELD

The present application relates to a reflow oven, in particular to an oxygen content detection system for a reflow oven and a control method thereof.

### BACKGROUND ART

A process known as “reflow soldering” is generally used in the course of printed circuit board production, to mount electronic components on the circuit board. In a typical reflow soldering process, solder paste (e.g., tin paste) is deposited in selected regions on the circuit board, and conductive wires of one or more electronic components are inserted into the deposited solder paste. The circuit board then passes through a reflow oven, in which the solder paste reflows (i.e., is heated to melting or reflow temperature) in a heating region, before cooling in a cooling region, to connect the conductive wires of the electronic components to the circuit board electrically and mechanically. The term “circuit board” used here includes substrate assemblies for electronic components of any type, e.g., wafer substrates. Inside the reflow oven, air or a substantially inert gas (such as nitrogen) is generally used as a working gas, with different working gases being used for circuit boards with different process requirements. A hearth of the reflow oven is filled with the working gas, and the circuit board undergoes soldering in the working gas when conveyed through the hearth by means of a conveying apparatus.

In the case of a reflow oven in which a substantially inert gas (such as nitrogen) is used as the working gas, external air will inevitably enter the hearth of the reflow oven as the circuit board is conveyed through the hearth of the reflow oven, and consequently, oxygen will be present in the hearth. If the oxygen concentration exceeds a certain level, this will have an adverse effect on the soldering of electronic components in the reflow oven, e.g., cause oxidation of the electronic components, etc. For this reason, a zirconia analyser is generally provided in the reflow oven to detect the content of oxygen in the reflow oven, and working gas is added to the hearth according to the oxygen content, in order to maintain the oxygen concentration at a desired level. However, in the course of operation of the reflow oven, elements/components (e.g., circuit boards, etc.) in the reflow oven will release certain substances at high temperatures, and these substances will be adsorbed on the surface of the zirconia tube of the zirconia analyser, causing failure of the zirconia analyser. In the prior art, operators generally open the hearth so that air enters the hearth and oxidizes the substances adsorbed on the surface of the zirconia analyser, thus allowing the zirconia analyser to return to normal. When implemented, this method requires that reflow oven operation be stopped, and once the zirconia analyser has returned to normal, it is further necessary to pass working gas into the hearth for a certain period of time in order to enable the working gas in the hearth to meet the desired requirement; thus, the method appears to be extremely tedious and not economical.

### SUMMARY OF THE INVENTION

The present application provides an oxygen content detection system for detecting an oxygen content in a hearth of a reflow oven, the system comprising: a zirconia analyser, an air source, a mass flow valve and a first throttle valve. The zirconia analyser comprises: a signal processing apparatus, a housing and a probe. The housing is connected to the signal processing apparatus, and the housing has a detection port, the detection port being configured to enable a gas to be detected that comes from inside the hearth to enter a cavity of the housing via the detection port; the probe is disposed in the cavity of the housing, one end of the probe being connected to the signal processing apparatus, the probe being configured to detect an oxygen concentration in the gas to be detected that enters the cavity of the housing, and the signal processing apparatus receiving and processing a detection result of the probe in order to generate an oxygen concentration signal; the housing is further provided with a communication hole, the communication hole being in fluid communication with the cavity of the housing. The air source is configured to be connected to the communication hole via a connection pathway, in order to input air to the cavity of the housing. The mass flow valve is disposed in the connection pathway, and configured to adjust the amount of air delivered to the cavity of the housing from the air source according to the oxygen concentration signal. The first throttle valve is disposed in the connection pathway, in order to adjust the flow speed of air in the connection pathway.

In the oxygen content detection system according to the present application, when the oxygen concentration, indicated by the oxygen concentration signal, in the gas to be detected that comes from the hearth is within a pre-set range, the zirconia analyser is in an operational state; and when the oxygen concentration, indicated by the oxygen concentration signal, in the gas to be detected that comes from the hearth drops sharply to close to 0, the zirconia analyser is in a failed state. When the zirconia analyser is in the failed state, oxygen in the air that is inputted to the cavity of the housing by means of the air source can react with substances adsorbed on the probe, so that the zirconia analyser is restored to the operational state from the failed state.

The oxygen content detection system according to the present application further comprises a controller, the controller being configured to be able to receive the oxygen concentration signal, and being configured to: keep the mass flow valve in a closed state when the oxygen concentration in the hearth as indicated by the oxygen concentration signal is within the pre-set range; and open the mass flow valve to begin inputting air to the cavity of the housing from the air source when the oxygen concentration in the hearth as indicated by the oxygen concentration signal drops sharply to close to 0.

In the oxygen content detection system according to the present application, the controller is configured to retrieve and lock an oxygen concentration signal preceding failure of the zirconia analyser, and can compare an oxygen concentration signal received during delivery of air to the cavity of the housing from the air source with the pre-failure oxygen concentration signal, and control the degree of opening of the mass flow valve according to the comparison result, so as to adjust the amount of air delivered to the cavity of the housing from the air source.

In the oxygen content detection system according to the present application, the controller is configured to close the mass flow valve when the oxygen concentration signal received during delivery of air to the cavity of the housing from the air source reaches the oxygen concentration signal preceding failure of the zirconia analyser.

In the oxygen content detection system according to the present application, the cavity of the housing of the zirconia analyser is in communication with a peak value zone of the reflow oven via the detection port, in order to utilize the temperature of the peak value zone to enable oxygen in the air from the air source to react with substances adsorbed on the probe.

The present application further provides a control method for an oxygen content detection system of a reflow oven, the oxygen content detection system comprising a zirconia analyser, the zirconia analyser being able to detect an oxygen content of gas in the reflow oven. The control method comprises: monitoring an oxygen concentration signal generated by the zirconia analyser during operation of the reflow oven, and when an oxygen concentration, indicated by the oxygen concentration signal of the zirconia analyser, in a gas to be detected that comes from the reflow oven is detected to drop sharply to close to 0, judging that the zirconia analyser is in a failed state, and performing the following steps to restore the zirconia analyser to an operational state from the failed state: inputting air to a cavity of the zirconia analyser, the cavity accommodating a probe; receiving an oxygen concentration signal generated by the zirconia analyser while inputting air, and comparing it with an oxygen concentration signal preceding failure of the zirconia analyser; when the oxygen concentration signal received while inputting air reaches the oxygen concentration signal preceding failure of the zirconia analyser, judging that the zirconia analyser is in the operational state, and stopping the input of air to the cavity accommodating the probe of the zirconia analyser.

In the method according to the present application, the step of inputting air to the cavity accommodating the probe of the zirconia analyser comprises inputting air to the cavity accommodating the probe of the zirconia analyser from an air source; and the method further comprises: providing a mass flow valve and a first throttle valve on a connection pathway between the air source and the zirconia analyser to control the amount and speed of air.

In the method according to the present application, when the steps are performed to restore the zirconia analyser to the operational state from the failed state, the reflow oven maintains operation.

In the method according to the present application, the zirconia analyser detects a gas from a peak value zone of the reflow oven, in order to utilize the temperature of the peak value zone to enable oxygen in the air from the air source to react with substances adsorbed on the probe.

### BRIEF DESCRIPTION OF THE DRAWINGS

FIG. 1 is a schematic diagram of an embodiment of a reflow oven 100 of the present application and a gas control system thereof.

FIG. 2 is a schematic diagram of an oxygen content detection system 120 of the gas control system shown in FIG. 1.

FIG. 3 is a schematic chart of some of the steps of a control method 300 that uses the oxygen content detection system 120 shown in FIG. 2.

FIG. 4 is a schematic diagram of an embodiment of a controller 121 in FIG. 1.

### DETAILED DESCRIPTION OF EMBODIMENTS

Various particular embodiments of the present application are described below with reference to the drawings, which form part of this specification. It should be understood that although terms indicating direction, such as “front”, “rear”, “up”, “down”, “left”, “right”, “inner”, “outer”, “top” and “bottom”, etc. are used in the present application to describe various exemplary structural parts and elements of the present application, these terms are used here solely to facilitate explanation, and determined on the basis of the exemplary orientations shown in the drawings. Since the embodiments disclosed in the present application may be arranged in different directions, these terms indicating direction are merely illustrative and should not be regarded as limiting.

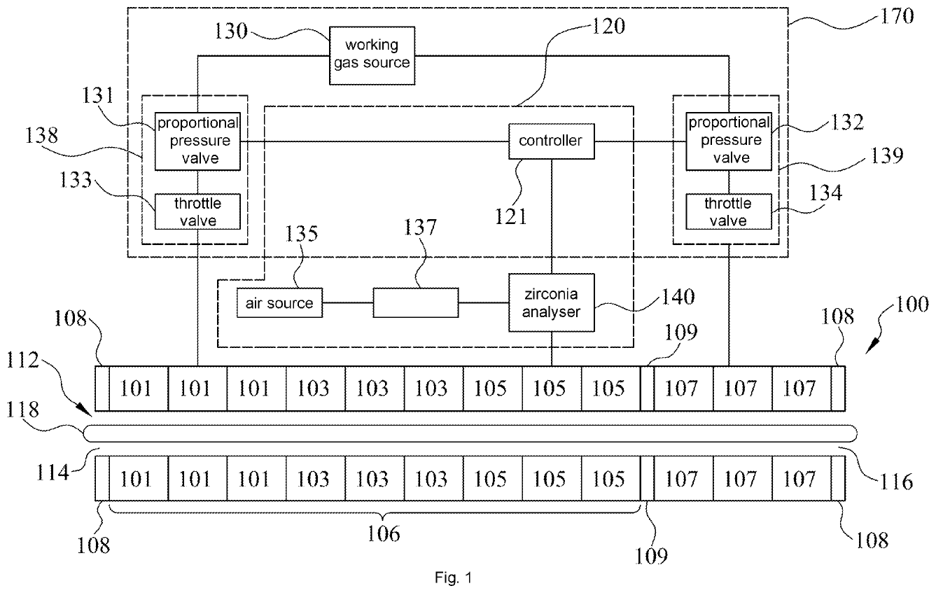

FIG. 1 is a schematic diagram of an embodiment of a reflow oven 100 of the present application and a gas control system thereof, being intended to show the principal constituent parts of the reflow oven 100 and the gas control system thereof. As shown in FIG. 1, the reflow oven 100 comprises a hearth 112, as well as preheating zones 101, uniform-temperature zones 103, peak value zones 105 and cooling zones 107. A separating gas discharge zone 109 is also provided between the peak value zones 105 and the cooling zones 107. The hearth 112 runs through the preheating zones 101, uniform-temperature zones 103, peak value zones 105 and cooling zones 107; the preheating zones 101, uniform-temperature zones 103, peak value zones 105 and cooling zones 107 are in fluid communication via the hearth 112. The hearth 112 comprises an inlet 114 and an outlet 116. The reflow oven 100 is further provided with a conveying apparatus 118; the conveying apparatus 118 is arranged to run through the hearth 112, and is used to deliver circuit boards to be processed into the hearth 112 through the inlet 114 of the hearth 112, and output circuit boards which have been processed in the reflow oven 100 from the hearth 112 through the outlet 116 of the hearth 112.

The preheating zones 101, uniform-temperature zones 103 and peak value zones 105 together form a heating zone 106. In the embodiment shown in FIG. 1, the heating zone 106 comprises three preheating zones 101, three uniform-temperature zones 103 and three peak value zones 105. The preheating zones 101, uniform-temperature zones 103 and peak value zones 105 are connected together sequentially, and gradually increase in temperature. In the preheating zones 101 and uniform-temperature zones 103, the circuit boards are heated, and some of the flux in the solder paste distributed on the circuit board will vaporize. The temperature of the peak value zones 105 is higher than that of the preheating zones 101 and uniform-temperature zones 103, and the solder paste melts in the peak value zones 105. The peak value zones 105 are also higher-temperature regions in which VOCs (e.g., turpentine, resin) will vaporize. In the embodiment shown in FIG. 1, the reflow oven 100 comprises three cooling zones 107. Once a circuit board has been conveyed into the cooling zones 107 from the heating zone 106, solder paste is cooled and hardens in soldering regions of the circuit board, thereby connecting electronic components to the circuit board. It is worth noting that the numbers of preheating zones 101, uniform-temperature zones 103, peak value zones 105 and cooling zones 107 in the reflow oven are not limited to the embodiment shown in FIG. 1, and can vary according to the product to be soldered and different soldering processes.

The separating gas discharge zone 109 is provided in a connection region between the heating zone 106 and the cooling zones 107. The separating gas discharge zone 109 can extract or discharge gas from the hearth 112, thereby impeding or reducing the ingress of gas containing volatile contaminants from the heating zone 106 into the cooling zones 107. In addition, by extracting or discharging gas from the hearth 112, the separating gas discharge zone 109 can also be used as a temperature barrier region, isolating the high-temperature heating zone 106 from the low-temperature cooling zones 107.

The reflow oven 100 of the present application uses nitrogen as a working gas. The reflow oven 100 is equipped with a working gas source 130, for conveying clean working gas to the hearth 112. The reflow oven 100 further comprises gas separation zones 108 located at the inlet 114 and outlet 116 of the hearth 112. The gas separation zones 108 are used for supplying nitrogen towards the hearth 112 and thereby forming nitrogen curtains, by means of which it is possible to prevent air in the external environment from entering the hearth 112. The reflow oven 100 is also equipped with a gas discharge apparatus (not shown), for discharging gas containing volatile contaminants from the hearth 112. The gas discharge apparatus is generally connected in a higher-temperature region of the reflow oven 100, such as the constant-temperature zones 103, peak value zones 105 or separating gas discharge zone 109. When the reflow oven 100 is in a state of processing circuit boards, the gas discharge apparatus will remain in an operational state at all times, in order to maintain the cleanliness of gas in the hearth 112. In this process, it is also necessary to input clean nitrogen from the working gas source 130 at all times, in order to maintain the working atmosphere and working pressure required by the hearth 112.

Despite the provision of the gas separation zones 108 to form the nitrogen curtains, a relatively small amount of air from the external environment will inevitably enter the hearth 112 as the conveying apparatus 118 conveys circuit boards into or out of the hearth 112; for this reason, the working gas in the hearth 112 will always be mixed with oxygen. Different soldering processes have different requirements for the oxygen concentration level in the hearth 112, generally 500-5000 ppm (parts per million). It is desirable that the oxygen concentration in the hearth 112 be maintained close to the value required by a specific soldering process. This makes it possible to meet soldering quality requirements and also saves nitrogen.

To this end, the reflow oven 100 of the present application is also equipped with a gas control system. Still referring to FIG. 1, the gas control system comprises an oxygen content detection system 120 and a nitrogen gas input system 170; the oxygen content detection system 120 is used for detecting the oxygen content in the hearth 112 of the reflow oven 100, and the nitrogen gas input system 170 decides whether to add nitrogen to the hearth 112 according to a detection result of the oxygen content detection system 120, so as to maintain the oxygen concentration in the hearth 112 at the desired level.

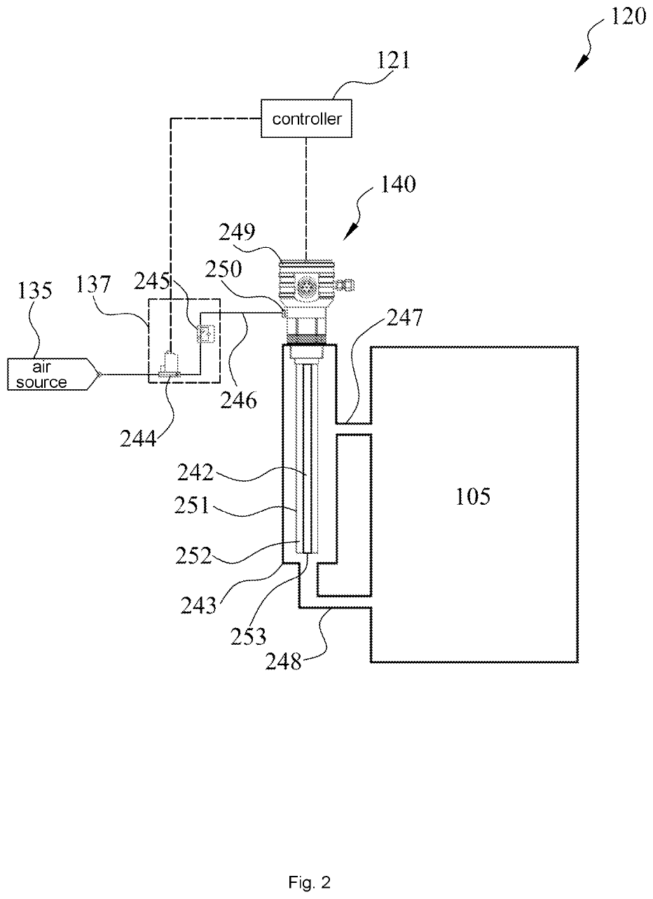

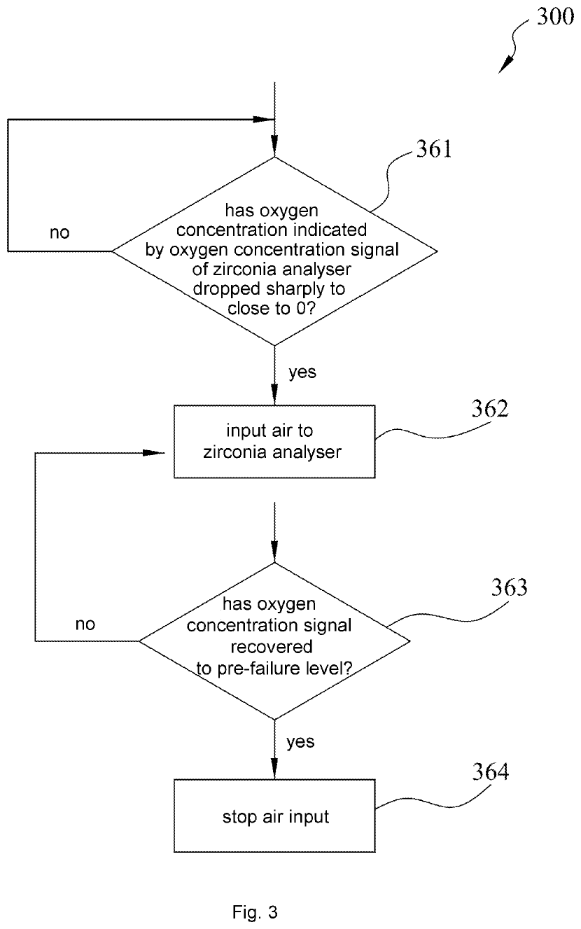

The oxygen content detection system 120 comprises a zirconia analyser 140, an air source 135, a first gas input valve apparatus 137 and a controller 121. The zirconia analyser 140 is in contact with gas in the peak value zones 105 of the reflow oven 100, and is used to detect the oxygen concentration in the peak value zones 105. Within the reflow oven 100, the temperature is highest in the peak value zones 105, which are also regions which affect soldering quality to a greater extent in the soldering process. Thus, by detecting the oxygen concentration in the peak value zones 105, and adjusting the amount of nitrogen supplied according to the detected oxygen concentration in the peak value zones 105, it is possible to maintain the oxygen concentration in the peak value zones 105 at the target set value required by the soldering process, and thereby possible to significantly improve the soldering quality. In addition, as stated above, the peak value zones 105 are higher-temperature regions in which VOCs (e.g., turpentine, resin) and other substances will vaporize. Thus, the vaporized VOCs and other substances will be adsorbed on the surface of the probe of the zirconia analyser 140. When the substances adsorbed on the surface of the probe have built up to a certain degree, the probe will lose sensitivity to oxygen, causing the zirconia analyser 140 to fail. The air source 135 is connected to the zirconia analyser 140 via the first gas input valve apparatus 137, and the air source 135 is configured to be able to restore the zirconia analyser 140 to an operational state from a failed state by delivering air to the zirconia analyser 140; this will be described in greater detail in FIGS. 2 and 3.

The nitrogen gas input system 170 comprises a working gas source (nitrogen source) 130, a second gas input valve apparatus 138, a third gas input valve apparatus 139 and the controller 121. That is to say, the oxygen content detection system 120 is in communicative connection with the nitrogen gas input system 170 via the controller 121. The second gas input valve apparatus 138 and third gas input valve apparatus 139 are used to establish fluid communication between the working gas source 130 and the hearth 112 in a controllable fashion, in order to input nitrogen into the hearth 112. The controller 121 can control the degree of opening of the second gas input valve apparatus 138 and the third gas input valve apparatus 139 according to an oxygen concentration signal measured by the oxygen content detection system 120, in order to adjust the amount of nitrogen inputted into the hearth 112, and thereby adjust the oxygen concentration in the hearth 112. Here, the degree of opening means the degree to which the valve is opened, between 0 and 100%, wherein a degree of opening of 0 means that the valve is closed, and a degree of opening of 100% means that the valve is completely open.

In the embodiment shown in FIG. 1, the second gas input valve apparatus 138 and third gas input valve apparatus 139 each comprise a proportional pressure valve and a throttle valve. Specifically, the second gas input valve apparatus 138 comprises a second proportional pressure valve 131 and a second throttle valve 133, and the third gas input valve apparatus 139 comprises a third proportional pressure valve 132 and a third throttle valve 134. The second proportional pressure valve 131 and third proportional pressure valve 132 are connected to the working gas source 130, and are able to adjust the amount of nitrogen received from the working gas source 130 in a controllable fashion. The second throttle valve 133 and third throttle valve 134 are connected to the second proportional pressure valve 131 and third proportional pressure valve 132 respectively, and are able to adjust gas flow speeds according to the nitrogen amounts adjusted by the second proportional pressure valve 131 and third proportional pressure valve 132.

The second gas input valve apparatus 138 establishes fluid communication between the preheating zones 101 and the working gas source 130; the third gas input valve apparatus 139 establishes fluid communication between the cooling zones 107 and the working gas source 130. In each region of the heating zone 106, the gas temperature increases gradually from left to right, and different regions have different requirements for the gas temperature, in order to meet different soldering process requirements. By supplying nitrogen to the hearth 112 at the positions of the preheating zone 101 close to the inlet 114 and the cooling zone 107 close to the outlet 116, the nitrogen at room temperature from the working gas source 130 can be caused to enter lower-temperature regions, thereby avoiding any obvious impact on the gas temperature in the higher-temperature regions.

FIG. 2 is a schematic diagram of the oxygen content detection system 120 of the gas control system shown in FIG. 1, intended to show specific constituent parts of the oxygen content detection system 120. As shown in FIG. 2, the air source 135 is connected to the zirconia analyser 140 via a connection pathway 246. The first gas input valve apparatus 137 is disposed in the connection pathway 246. The first gas input valve apparatus 137 comprises a mass flow valve 244 and a first throttle valve 245; the mass flow valve 244 can adjust the amount of air conveyed to the zirconia analyser 140 from the air source 135, and the first throttle valve 245 can adjust the flow speed of air in the connection pathway 246. The mass flow valve 244 and first throttle valve 245 are disposed in the connection pathway 246 in sequence in the direction from the air source 135 to the zirconia analyser 140. That is to say, in the process of air flowing from the air source 135 towards the zirconia analyser 140, the air first passes through the mass flow valve 244 to adjust the total amount of air flowing towards the zirconia analyser 140. It must be explained that, compared with the second proportional pressure valve 131 and the third proportional pressure valve 132, the mass flow valve 244 can control the amount of air entering the zirconia analyser 140 more precisely. A certain amount of air adjusted by the mass flow valve 244 then passes through the first throttle valve 245; the first throttle valve 245 can adjust the flow speed of the air, thereby adjusting the flow speed of the air to a suitable range, in order to avoid too high a flow speed of air entering the zirconia analyser 140, which would cause a drop in temperature in the zirconia analyser 140. It is desirable that the temperature in the zirconia analyser 140 be maintained within a certain range; this is because certain temperature conditions are required for air to oxidize the substances adsorbed on the zirconia analyser 140, and if the air flow speed is too fast, this will cause a drop in temperature in the zirconia analyser 140, which will prevent the air entering the zirconia analyser 140 from effectively utilizing the temperature of the peak value zones 105 to oxidize the substances adsorbed on the zirconia analyser 140. In addition, the zirconia analyser 140 can only operate normally under high-temperature conditions (generally above 700° C.). When the temperature in the zirconia analyser 140 is unable to attain high-temperature conditions (e.g., falls to below 700° C.), then even if the air has in fact already oxidized the substances adsorbed on the zirconia analyser 140, it will be impossible to judge whether the substances adsorbed thereon have already been completely oxidized based on the oxygen concentration signal of the zirconia analyser 140, and thus impossible to judge whether the zirconia analyser has already been restored to an operational state. As a result, the air source 135 will continuously input air into the zirconia analyser 140. Of course, in other embodiments, a heater may be provided in the connection pathway 246, so that the air attains the desired temperature, e.g., close to or higher than 700° C., before entering the zirconia analyser 140.

The zirconia analyser 140 comprises a signal processing apparatus 249, a housing 251 and a probe 242. The housing 251 is connected to the signal processing apparatus 249. Most of the housing 251 is disposed in a gas collection chamber 243 of the peak value zones 105 of the reflow oven 100, for the purpose of contacting the working gas to be detected. The gas collection chamber 243 is disposed in such a way as to facilitate the installation and removal of the zirconia analyser 140; for example, the gas collection chamber 243 may be disposed in a place that is easily accessible by an operator. The gas collection chamber 243 is in fluid communication with the peak value zone 105 via communication ducts 247 and 248, and working gas is caused to flow into and/or flow out of the gas collection chamber 243 by means of a fan (not shown) disposed in the hearth 112. Of course, in other embodiments, the housing 251 of the zirconia analyser 140 may also be inserted into the peak value zone 105 directly.

The housing 251 has a cavity 252; the probe 242 is disposed in the cavity 252 of the housing 251 and connected to the signal processing apparatus 249. The end of the housing 251 that is opposite the signal processing apparatus 249 has a detection port 253; working gas can enter the cavity 252 of the zirconia analyser 140 through the detection port 253, and contact the probe 242 of the zirconia analyser 140. The probe 242 is a zirconia tube, which is a good oxygen ion conductor at high temperatures (generally higher than 700° C.). The zirconia tube is substantially in the form of a round tube closed at one end (not shown); a first platinum electrode (not shown) is provided outside the zirconia tube, and a second platinum electrode (not shown) is provided inside the zirconia tube. The first platinum electrode is in contact with working gas, and the second platinum electrode is in contact with reference air. At high temperatures, because the oxygen content in the working gas is different from the oxygen content in the reference air, the oxygen concentration difference causes oxygen ions to migrate from the second platinum electrode towards the first platinum electrode, and an electric potential generated causes oxygen ions to migrate in a reverse direction from the first platinum electrode towards the second platinum electrode. When these two types of migration have reached equilibrium, an electric potential signal related to the oxygen concentration difference is generated between the first platinum electrode and the second platinum electrode, and the signal processing apparatus 249 generates a signal of the oxygen concentration in the working gas according to the electric potential signal.

A communication hole 250 is further provided at the end of the housing 251 that is close to the signal processing apparatus 249; air from the air source 135 enters the cavity 252 of the housing 251 through the communication hole 250, in order to restore the zirconia analyser 140 to an operational state from a failed state. Specifically, in a high-temperature state, the air passed into the zirconia analyser 140 can oxidize VOCs and other substances adsorbed on the outside of the probe 242, thereby restoring the zirconia analyser 140 to an operational state from a failed state.

The controller 121 is in communicative connection with the mass flow valve 244 and the signal processing apparatus 249 of the zirconia analyser 140, and can control the degree of opening of the mass flow valve 244 according to the oxygen concentration signal generated by the signal processing apparatus 249, and thereby adjust the amount of air entering the zirconia analyser 140; the specific control process will be described with reference to FIG. 3.

FIG. 3 is a schematic chart of some of the steps of a control method 300 that uses the oxygen content detection system 120 shown in FIG. 2, being intended to show a method for judging whether the zirconia analyser 140 has failed and restoring it to a normal state from a failed state. In the course of normal operation of the reflow oven 100, the oxygen content detection system 120 monitors the oxygen content in the peak value zone 105 of the reflow oven 100 in real time. Specifically, as stated above, different soldering processes have different requirements for the oxygen concentration level in the hearth 112, and generally will allow deviation in the oxygen concentration within a certain range. Suppose that a soldering process requires an oxygen concentration of 500 ppm, with a deviation of 20%; then an oxygen concentration of 600 ppm indicated by the oxygen concentration signal of the zirconia analyser 140 can be considered to be a normal operating state. When the oxygen concentration is greater than 600 ppm, the controller 121 switches on the second gas input valve apparatus 138 and the third gas input valve apparatus 139, so as to input nitrogen into the reflow oven 100 from the working gas source 130; when the oxygen concentration indicated by the oxygen concentration signal of the zirconia analyser 140 reaches 500 ppm, the controller 121 switches off the second gas input valve apparatus 138 and the third gas input valve apparatus 139. When the zirconia analyser 140 fails, i.e., when the amount of VOCs and other substances released by the product and adsorbed on the surface of the probe 242 of the zirconia analyser 140 reaches a certain level, the probe 242 of the zirconia analyser 140 will be unable to make sufficient contact with the working gas, and will thereby lose sensitivity to oxygen.

In step 361 shown in FIG. 3, monitoring is carried out to determine whether the oxygen concentration indicated by the oxygen concentration signal of the zirconia analyser 140 drops sharply to close to 0. If it does, the zirconia analyser 140 is judged to be in a failed state, and the method moves to step 362; otherwise, the zirconia analyser 140 is judged to be in a normal operating state, and step 361 is continued. It must be explained that the statement “the oxygen concentration indicated by the oxygen concentration signal of the zirconia analyser 140 drops sharply to close to 0” means that the oxygen concentration indicated by the oxygen concentration signal drops from 600 ppm or less than 600 ppm (e.g., 450 ppm) to close to 0 (e.g., 20 ppm or less) within 1 second or a shorter time.

The controller 121 will store the oxygen concentration signal of the zirconia analyser 140 in real time throughout the process. When the zirconia analyser 140 is in a failed state, the oxygen concentration signal preceding failure of the zirconia analyser 140 is retrieved and locked by the controller 121. For example, if the oxygen concentration indicated by the oxygen concentration signal of the zirconia analyser 140 drops from 450 ppm to close to 0 within 1 second or a shorter time, then the pre-failure oxygen concentration signal is the oxygen concentration signal corresponding to an oxygen concentration of 450 ppm.

In step 362, the controller 121 switches on the mass flow valve 244 so that air flows towards the zirconia analyser 140 from the air source 135, and the method then moves to step 363. It must be explained that in this embodiment, a nitrogen gas input control module and a zirconia restoring module are stored in the controller 121. When the zirconia analyser 140 is operating normally, the controller 121 calls the nitrogen gas input control module, at which time the zirconia restoring module is not called, i.e., the mass flow valve 244 is in a closed state; when failure of the zirconia analyser 140 is detected, the controller 121 switches to the zirconia restoring module, at which time the nitrogen gas input control module is not called, and both the second gas input valve apparatus 138 and the third gas input valve apparatus 139 are in a switched-off state. Of course, the controller 121 may also call the nitrogen gas input control module and zirconia restoring module at the same time, and input nitrogen into the reflow oven 100 while restoring the zirconia analyser 140 to an operational state from a failed state, in order to prevent too high an oxygen content in the reflow oven 100 when the oxygen content in the reflow oven 100 cannot be detected, and the consequent adverse effects on the product.

In step 363, the controller 121 receives the oxygen concentration signal generated by the zirconia analyser 140 while controlling the mass flow valve 244 to input air to the zirconia analyser 140, compares the received oxygen concentration signal with the oxygen concentration signal preceding failure of the zirconia analyser 140, and judges whether the oxygen concentration signal has recovered to the level which it had before failure of the zirconia analyser. If so, then the method moves to step 364; otherwise, the method moves to step 362.

In the process of the received oxygen concentration signal and the oxygen concentration signal preceding failure of the zirconia analyser 140 being compared by the controller 121, the controller 121 also controls the degree of opening of the mass flow valve 244 according to the comparison result, and thereby adjusts the amount of air entering the zirconia analyser 140. For example, as the difference between the oxygen concentration signal of the zirconia analyser 140 received by the controller 121 and the oxygen concentration signal preceding failure of the zirconia analyser 140 steadily decreases, the controller 121 controls the mass flow valve 244 to reduce its degree of opening, so that the amount of air entering the zirconia analyser 140 decreases. This type of dynamic control, together with the precise adjustment of the mass flow valve 244, make it possible for only an extremely small amount of the air entering the zirconia analyser 140 to be left over after oxidizing the VOCs and other substances adsorbed on the zirconia analyser 140, so the left-over air will not have an effect on the subsequent operation of the zirconia analyser 140.

In step 364, the controller 121 switches off the mass flow valve 244, to stop the input of air to the zirconia analyser 140. When the oxygen concentration signal of the zirconia analyser 140 received by the controller 121 has recovered to the level which it had before failure of the zirconia analyser 140, i.e., when the oxygen concentration signal of the zirconia analyser 140 received by the controller 121 is the same as (equal to) the oxygen concentration signal preceding failure of the zirconia analyser 140, the controller 121 determines that the zirconia analyser 140 has been restored to an operational state from a failed state. At this time, the controller 121 closes the mass flow valve 244, stopping the input of air to the zirconia analyser 140, and switches to the nitrogen gas input control module.

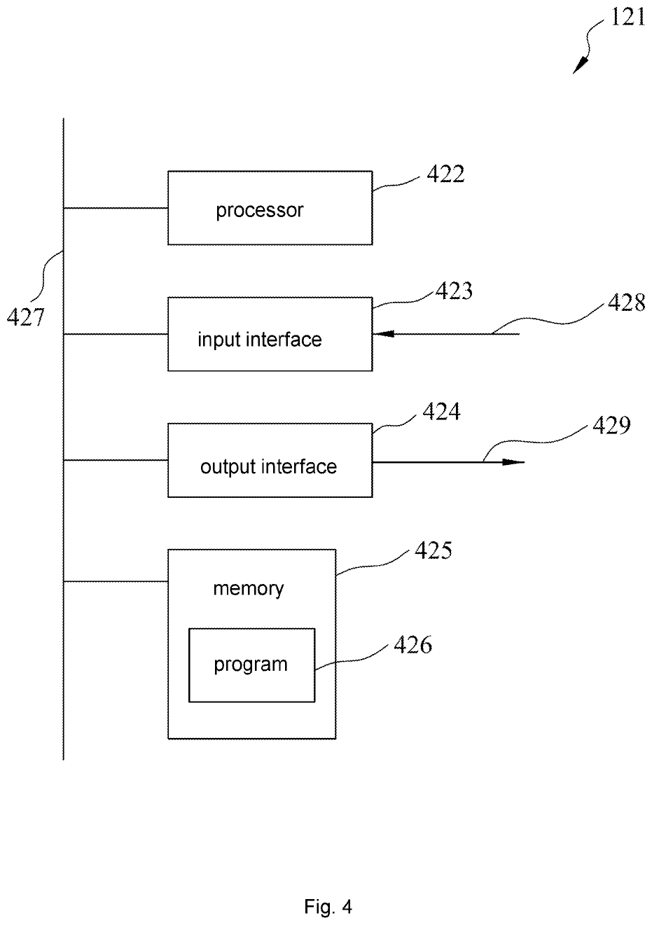

FIG. 4 is a schematic diagram of an embodiment of the controller 121 in FIG. 1. The controller 121 comprises a bus 427, a processor 422, an input interface 423, an output interface 424 and a memory 425 having a control program 426. The processor 422, input interface 423, output interface 424 and memory 425 are in communicative connection via the bus 427, such that the processor 422 is able to control the operation of the input interface 423, output interface 424 and memory 425. The memory 425 is used for storing programs, instructions and data; the processor 422 reads programs, instructions and data from the memory 425, and can write data into the memory 425.

The input interface 423 receives signals and data via a connection 428, e.g., a signal indicating the operating state of the reflow oven 100, the oxygen concentration signal issued by the zirconia analyser 140, and various manually inputted parameters, etc. The output interface 424 sends signals and data via a connection 429, e.g., sends controls signals for adjusting the degree of opening to the mass flow valve 244, the second proportional pressure valve 131 and the third proportional pressure valve 132. Within the memory 425 are stored the control program, target set values of oxygen concentration that are set in advance, the oxygen concentration signal preceding failure of the zirconia analyser 140, the nitrogen gas input control module and the zirconia restoring module, and other data. Various types of parameters may be set in advance in the process of production, and it is also possible for various types of parameter to be set by manual input or data import. The processor 422 acquires various signals, data, programs and instructions from the input interface 423 and the memory 425, performs corresponding processing, and produces an output via the output interface 424.

The oxygen content detection system 120 of the present application can enable the zirconia analyser 140 to be restored to a normal operating state after failure, and can achieve “online recovery”, i.e., perform failure recovery of the zirconia analyser 140 when the reflow oven 100 is still in a normal operating state, without the need to stop the operation of the reflow oven 100. Thus, the oxygen content detection system 120 of the present application can achieve failure recovery of the zirconia analyser 140 in a time-saving and cost-reducing way.

Although the present application is described with reference to the particular embodiments shown in the drawings, it should be understood that the oxygen content detection system of the present application may have many variant forms without departing from the spirit, scope and background of the teaching of the present application. Those skilled in the art will also realize that the structural details in the embodiments disclosed in the present application can be changed in different ways, all of which fall within the spirit and scope of the present application and claims.

1. An oxygen content detection system (120), for detecting an oxygen content in a hearth (112) of a reflow oven (100), characterized in that the oxygen content detection system (120) comprises:
a zirconia analyser (140), the zirconia analyser (140) comprising:
a signal processing apparatus (249);
a housing (251), the housing (251) being connected to the signal processing apparatus (249), and the housing (251) having a detection port (253), the detection port (253) being configured to enable a gas to be detected that comes from inside the hearth (112) to enter a cavity (252) of the housing (251) via the detection port (253); and
a probe (242), the probe (242) being disposed in the cavity (252) of the housing (251), one end of the probe (242) being connected to the signal processing apparatus (249), the probe (242) being configured to detect an oxygen concentration in the gas to be detected that enters the cavity (252) of the housing (251), and the signal processing apparatus (249) receiving and processing a detection result of the probe (242) in order to generate an oxygen concentration signal;
wherein the housing (251) is further provided with a communication hole (250), the communication hole (250) being in fluid communication with the cavity (252) of the housing (251);
an air source (135), the air source (135) being configured to be connected to the communication hole (250) via a connection pathway (246), in order to input air to the cavity (252) of the housing (251);
a mass flow valve (244), the mass flow valve (244) being disposed in the connection pathway (246), and configured to adjust the amount of air delivered to the cavity (252) of the housing (251) from the air source (135) according to the oxygen concentration signal; and
a first throttle valve (245), the first throttle valve (245) being disposed in the connection pathway (246), in order to adjust the flow speed of air in the connection pathway (246).

2. The oxygen content detection system (120) as claimed in claim 1, characterized in that:
when the oxygen concentration, indicated by the oxygen concentration signal, in the gas to be detected that comes from the hearth (112) is within a pre-set range, the zirconia analyser (140) is in an operational state; and when the oxygen concentration, indicated by the oxygen concentration signal, in the gas to be detected that comes from the hearth (112) drops sharply to close to 0, the zirconia analyser (140) is in a failed state;
wherein, when the zirconia analyser (140) is in the failed state, oxygen in the air that is inputted to the cavity (252) of the housing (251) by means of the air source (135) can react with substances adsorbed on the probe (242), so that the zirconia analyser (140) is restored to the operational state from the failed state.

3. The oxygen content detection system (120) as claimed in claim 2, characterized in that:
it further comprises a controller (121), the controller (121) being configured to be able to receive the oxygen concentration signal, and being configured to: keep the mass flow valve (244) in a closed state when the oxygen concentration in the hearth (112) as indicated by the oxygen concentration signal is within the pre-set range; and open the mass flow valve (244) to begin inputting air to the cavity (252) of the housing (251) from the air source (135) when the oxygen concentration in the hearth (112) as indicated by the oxygen concentration signal drops sharply to close to 0.

4. The oxygen content detection system (120) as claimed in claim 3, characterized in that:
the controller (121) is configured to retrieve and lock an oxygen concentration signal preceding failure of the zirconia analyser (140), and can compare an oxygen concentration signal received during delivery of air to the cavity (252) of the housing (251) from the air source (135) with the pre-failure oxygen concentration signal, and control the degree of opening of the mass flow valve (244) according to the comparison result, so as to adjust the amount of air delivered to the cavity (252) of the housing (251) from the air source (135).

5. The oxygen content detection system (120) as claimed in claim 4, characterized in that:
the controller is configured to close the mass flow valve (244) when the oxygen concentration signal received during delivery of air to the cavity (252) of the housing (251) from the air source (135) reaches the oxygen concentration signal preceding failure of the zirconia analyser (140).

6. The oxygen content detection system (120) as claimed in claim 1, characterized in that:
the cavity (252) of the housing (251) of the zirconia analyser (140) is in communication with a peak value zone (105) of the reflow oven (100) via the detection port (253), in order to utilize the temperature of the peak value zone (105) to enable oxygen in the air from the air source (135) to react with substances adsorbed on the probe (242).

7. A control method (300) for an oxygen content detection system (120) of a reflow oven (100), the oxygen content detection system (120) comprising a zirconia analyser (140), the zirconia analyser (140) being able to detect an oxygen content of gas in the reflow oven (100), characterized by comprising:
monitoring an oxygen concentration signal generated by the zirconia analyser (140) during operation of the reflow oven (100), and when an oxygen concentration, indicated by the oxygen concentration signal of the zirconia analyser (140), in a gas to be detected that comes from the reflow oven (100) is detected to drop sharply to close to 0, judging that the zirconia analyser (140) is in a failed state, and performing the following steps to restore the zirconia analyser (140) to an operational state from the failed state:
inputting air to a cavity (252) of the zirconia analyser (140), the cavity accommodating a probe (242);
receiving an oxygen concentration signal generated by the zirconia analyser (140) while inputting air, and comparing it with an oxygen concentration signal preceding failure of the zirconia analyser (140);
when the oxygen concentration signal received while inputting air reaches the oxygen concentration signal preceding failure of the zirconia analyser (140), judging that the zirconia analyser (140) is in the operational state, and stopping the input of air to the cavity (252) accommodating the probe (242) of the zirconia analyser (140).

8. The method (300) as claimed in claim 7, characterized in that:
the step of inputting air to the cavity (252) accommodating the probe (242) of the zirconia analyser (140) comprises inputting air to the cavity (252) accommodating the probe (242) of the zirconia analyser (140) from an air source (135); and
the method further comprises: providing a mass flow valve (244) and a first throttle valve (245) on a connection pathway (246) between the air source (135) and the zirconia analyser (140) to control the amount and speed of air.

9. The method (300) as claimed in claim 7, characterized in that:
when the steps are performed to restore the zirconia analyser (140) to the operational state from the failed state, the reflow oven (100) maintains operation.

10. The method (300) as claimed in claim 9, characterized by further comprising:
the zirconia analyser (140) detecting a gas from a peak value zone (105) of the reflow oven (100), in order to utilize the temperature of the peak value zone (105) to enable oxygen in the air from the air source (135) to react with substances adsorbed on the probe (242).
